(19) United States
(12) Patent Application Publication
(10) Pub. No.: US 2019/0097110 A1
(43) Pub. Date: Mar. 28, 2019

(54) PHOTOELECTRIC DEVICE AND SUBSTRATE THEREOF

(71) Applicant: KAISTAR Lighting (Xiamen) Co., Ltd, Xiamen (CN)

(72) Inventors: JINGQIONG ZHANG, Xiamen (CN); TSUNGCHIEH LIN, Xiamen (CN)

(21) Appl. No.: 16/127,227

(22) Filed: Sep. 11, 2018

(30) Foreign Application Priority Data
Sep. 27, 2017 (CN) 201710888073.2

(51) Int. Cl. H01L 33/64; H01L 25/075; H01L 33/62

(52) U.S. Cl. CPC H01L 33/644; H01L 25/0753; H01L 33/60; H01L 33/642; H01L 33/641; H01L 33/62

(57) ABSTRACT

A substrate for securing a photoelectric device chip is provided. The substrate includes a metal base and a dielectric layer. The metal base includes a die bonding region and a peripheral region surrounding the die bonding region, and the die bonding region is for securing the photoelectric device chip. The dielectric layer is disposed on the metal base and located in the peripheral region to define the die bonding region; the metal base is formed with at least one groove corresponding to the die bonding region, and the at least one groove is filled with a thermally conductive filler; and a filling density of the thermally conductive filler in unit of volume of the metal base is gradually reduced along a direction from a center to an edge of the die bonding region. Heat conducting efficiencies of various regions of the substrate are controllable and adjustable.

### TECHNICAL FIELD

The disclosure relates to a photoelectric technical field, and more particularly to a photoelectric device and a substrate.

### DESCRIPTION OF RELATED ART

Nowadays, light-emitting diodes (LEDs) have stepped in various realms of daily life, which can bring enjoyment and convenience.

As the applications of LED products, the quality requirement on photoelectric devices is higher and higher. LED chips are concentrated on a LED substrate to form a light-emitting surface, and therefore a heat dissipation efficiency and a thermal uniformity of the LED substrate are critical factors in affecting quality of a photoelectric device. The low heat dissipation efficiency and uneven thermal distribution will severely degrade the reliability of the entire photoelectric device, especially to a photoelectric device with high power density.

A conventional photoelectric device includes a substrate, and a number of LED chips mounted on the substrate. LED chips will generate heat in operation, and the heat will accumulate along with the operational time until heat balance. The thermal distribution on the entire light-emitting surface of a photoelectric device with regular power density is relatively even, a temperature difference between the center and an edge of the light-emitting surface is approximately 7° C.; but large amounts of LED chips arranged densely in the photoelectric device with high power density can cause the uneven thermal distribution. Adopting a thermometer (IR Image) to scan the thermal distribution of the light-emitting surface of the photoelectric device from left to right, it can be learnt from FIG. 1 that the central temperature is far higher than the marginal temperature of the light-emitting surface, and a temperature difference therebetween approximately is 22° C.; the temperature detection process has been repeated twice, and the temperature in the first time is similar to that in the second time.

The reasons contributing to the problems above include that:

(1) In a photoelectric device of high power density integrated with multiple LED chips, the number of chips mounted on the light-emitting surface is relatively large, and distances among LED chips is smaller than 0.5 mm, and such small space can hardly achieve the cooling goal simply by adjusting the arrangement of LED chips to expand the distances.

(2) Junction temperature differences are considerable among LED chips. Thermal resistances detected in a thermal resistance test are mean values, and the junction temperature Tj calculated by the thermal resistance also is a mean value; the junction temperature of the chip in the position with the highest temperature will exceed the junction temperature Tj calculated by the thermal resistance, which easily leads overheated chips to fail early.

(3) A coefficient of thermal expansion (CTE) of a conventional dielectric layer generally is 35˜45 ppm/C, which is larger than the CTE of the metal base that generally is 23˜24 ppm/C. As a stress generated by a material with relatively large CTE is the compressive stress, and the stress generated by a material with relatively small CTE is a tensile stress, the center of the light-emitting surface with high temperature can easily expand and deform to prevent the heat from being dissipated and accumulate heat, which results in higher central temperature.

However, as the chips in the photoelectric device with high power density are arranged densely, it is difficult to regulate the thermal distribution of the light-emitting surface by adjusting the distances among chips. Besides poor photoelectric parameters at hot state, quality and reliability of photoelectric devices will also be severely influenced.

### SUMMARY

In order to solve the problem above, the disclosure provides a substrate configured (i.e., structured and arranged) for securing a photoelectric device chip(s) thereon; the substrate includes a metal base and a dielectric layer.

The metal base includes a die bonding region and a peripheral region surrounding the die bonding region, and the die bonding region is configured for securing the photoelectric device chip thereon.

The dielectric layer is disposed on the metal base and located in the peripheral region to define the die bonding region. The metal base is formed with at least one groove corresponding to the die bonding region, the at least one groove is filled with a thermally conductive filler, and a filling density of the thermally conductive filler in unit of volume of the metal base is gradually reduced along a direction from a center to an edge of the die bonding region.

The disclosure further provides a photoelectric device including a number of photoelectric device chips, the substrate as above described, and a first electrode as well as a second electrode disposed on the substrate. The photoelectric device chips are securely mounted in the die bonding region of the metal base of the substrate and electrically connected with the first electrode and the second electrode. The first electrode and the second electrode are located in the peripheral region of the metal base.

The disclosure adopts a variety of manners to improve the structure of the substrate.

(1) The die bonding region of the substrate is defined with a groove(s) filled with a thermally conductive filler to enhance the heat conducting effect of the die bonding region.

(2) The shape and/or material of the thermally conductive filler is/are flexibly regulated and determined to distinguish heat conducting efficiencies of the die bonding region, which result in reducing temperature differences of various regions and unifying the temperature; the heat conducting effect of the disclosure is controllable and adjustable to economize the cost as well as maximize utilization of resources.

(3) The thickness and/or materials of the dielectric layer is/are regulated to decrease the compressive stress on edges of the substrate generated by the dielectric layer, so as to lower the possibility of deformation caused by central expansion of the substrate capable of further exacerbating heat accumulation.

### BRIEF DESCRIPTION OF THE DRAWINGS

FIG. 1 is a thermal distribution view of a light-emitting surface of a photoelectric device with high power density in the related art.

FIG. 2a is a top structural schematic view of a substrate of a first embodiment of the disclosure.

FIG. 2b is a cross-sectional structural schematic view of the substrate of the first embodiment of the disclosure.

FIG. 2c is a structural schematic view of a photoelectric device of the first embodiment of the disclosure.

FIG. 3a is a cross-sectional structural schematic view of a substrate of a second embodiment of the disclosure.

FIG. 3b is a top structural schematic view of a photoelectric device of the second embodiment of the disclosure.

FIG. 4a is a cross-sectional structural schematic view of a substrate of a third embodiment of the disclosure.

FIG. 4b is a top structural schematic view of the substrate of the third embodiment of the disclosure.

FIG. 4c is a cross-sectional structural schematic view of another substrate of the third embodiment of the disclosure.

FIG. 4d is a top structural schematic view of another substrate of the third embodiment of the disclosure.

FIG. 5a is a cross-sectional structural schematic view of a substrate of a fourth embodiment of the disclosure.

FIG. 5b is a cross-sectional structural schematic view of another substrate of the fourth embodiment of the disclosure.

FIG. 6a is a cross-sectional structural schematic view of a substrate of a fifth embodiment of the disclosure.

FIG. 6b is a cross-sectional structural schematic view of another substrate of the fifth embodiment of the disclosure.

FIG. 7 is a cross-sectional structural schematic view of a substrate of a sixth embodiment of the disclosure.

FIG. 8 is a top structural schematic view of a substrate of a seventh embodiment of the disclosure.

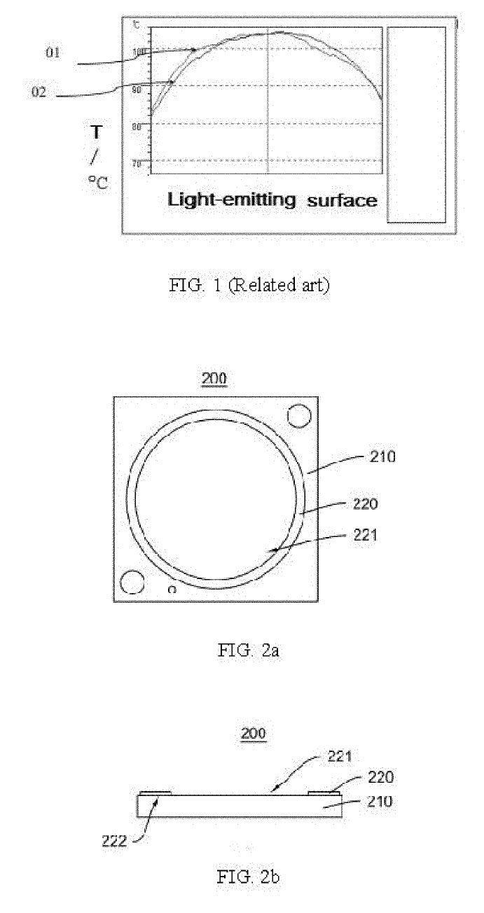

### DETAILED DESCRIPTION OF EMBODIMENTS

In the following, the disclosure will be introduced in detail with reference to concrete embodiments.

### First Embodiment

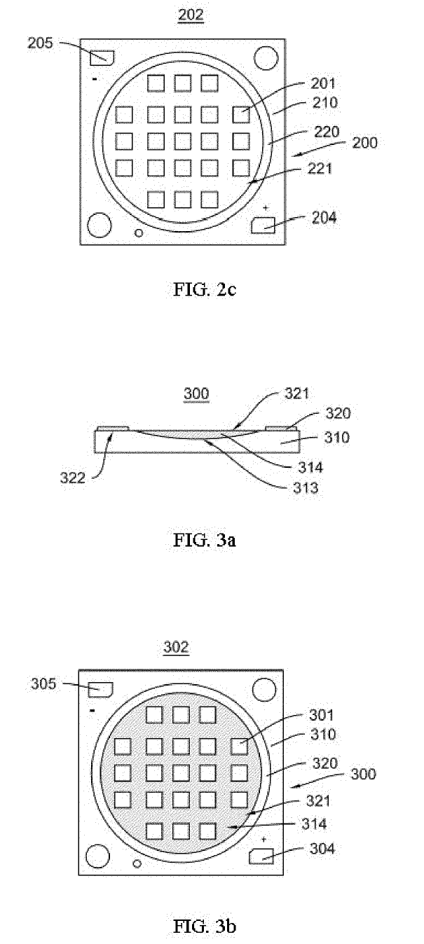

As shown in FIG. 2a, the embodiment provides a substrate 200, configured for securing of a photoelectric device chip(s) such as a light-emitting diode (LED) chip(s) (not shown). The substrate of the embodiment has an improved heat dissipation structure, especially adapting for centralized securing of large amounts of LED chips with high power density (whose power density is larger than 0.2 W/mm²); the improved heat dissipation structure allows the temperature of the light-emitting surface to be well-distributed, which guarantees the reliability of LED chips.

As shown in FIG. 2a and FIG. 2b, the substrate 200 of the embodiment includes a metal base 210 and a dielectric layer 220.

The metal base 210 includes a die bonding region 221 and a peripheral region 222 surrounding the die bonding region 221. The die bonding region 221 is configured for securing of the photoelectric device chips (not shown).

The dielectric layer 220 is disposed on the metal base 210 and located in the peripheral region to define the die bonding region 221. The die bonding region 221 can be round, square, rectangular or other shapes.

A material of the metal base 210 can be a mirror aluminum, whose coefficient of thermal expansion generally is 23˜24 ppm/° C. A thickness of the metal base 210 can be various, whose range can be 0.2˜1.0 mm.

The photoelectric device chips can be respectively arranged on a surface of the metal base 210 corresponding to the die bonding region 221 by a manner such as soldering, bonding or surface mounting. The amount of LED chips in the die bonding region 221 can be as large as possible according to the practical requirement. Accordingly, the metal base 210 corresponding to the die bonding region 221 accumulates heat along with the operation of the photoelectric device; the temperature of the metal base 210 corresponding to the center of the die bonding region 221 attains the maximum, and the temperature of the metal base 210 distant from the center of the die bonding region 221 gradually decreases. Correspondingly, a compressive stress generated in the center of the metal base 210 is maximal, which easily causes the center of the metal base 210 to be expanded and deformed, and aggravates the heat accumulation.

The selection of the dielectric layer 220 has critical influence on the stress relief of the metal base 210. The material of the dielectric layer 220 or the thickness thereof can be regulated to assist with the stress balance of the metal base 210 of the embodiment.

First, the material of the dielectric layer 220 can be adjusted.

The CTE of the dielectric layer 220 employed in the embodiment is lower than CTE of metal or ceramic; consequently the CTE of the dielectric layer of the embodiment is lower than CTE of the metal base, which is no higher than 23 ppm/° C. The generated tensile stress is reduced along with the reduction of CTE of the dielectric layer, and the force of the metal base 210 corresponding to the die bonding region can be accordingly reduced, which effectively suppresses the thermal deformation of the metal base.

Specifically, the dielectric layer of the embodiment includes a principal material (host material) and a filler added to the principal material, and CTE of the principal material is higher than CTE of the metal base; the CTE of the entire dielectric layer can be adjusted by introducing the filler. For instance, the principal material can adopt epoxy resin, whose CTE is around 60 ppm/° C.; the CTE of the dielectric layer 220 of the embodiment obtained by adding the filler into epoxy resin is 13 ppm/° C. (lower than glass transition temperature Tg).

Second, the thickness of the dielectric layer 220 can be adjusted.

A ratio of the thickness of the dielectric layer 220 to that of the metal base 210 of the embodiment can be larger than 0.5, which is preferably larger than 0.5 and smaller than 1. For instance, a general metal base 210 formed by mirror aluminum has four thickness specifications, which are 0.2 mm, 0.3 mm, 0.7 mm and 1.0 mm. In order to eliminate the heat stress, if the metal base 210 is 0.2 mm thick, the thickness of the dielectric layer 220 should be controlled to be larger than 0.1 mm; if the metal base 210 is 0.3 mm thick, the thickness of the dielectric layer 220 should be controlled to be larger than 0.15 mm; if the metal base 210 is 0.7 mm thick, the thickness of the dielectric layer 220 should be controlled to be larger than 0.35 mm; if the metal base 210 is 1.0 mm thick, the thickness of the dielectric layer should be controlled to be larger than 0.5 mm. In other words, a relation of the thickness of the dielectric layer and the thickness of the metal base can be that: the thickness of the dielectric layer is directly proportional to that of the metal base.

The embodiment further provides a photoelectric device 202 equipped with the substrate 200. As shown in FIG. 2c, the photoelectric device 202 includes a number of photoelectric device chips 201, the substrate 200, a first electrode 204 (e.g. negative electrode) and a second electrode 205 (e.g. positive electrode) disposed on the substrate. The photoelectric device chips 201 are securely mounted on the metal base 210 and corresponding to the die bonding region 221. The photoelectric device chips 201 are electrically connected with the first electrode 204 and the second electrode 205. The first electrode 204 and the second electrode 205 are fixed on the metal base 210 and corresponding to the outside of the dielectric layer 220. The photoelectric device chips can be light-emitting diode chips.

The substrate of the embodiment controls the CTE to be no higher than the CTE of the metal base by adjusting the material of the dielectric layer, which specifically is no higher than 23 ppm/° C., or controls the thickness of the dielectric layer to mutually neutralize the stresses generated by the metal base and the dielectric layer so as to prevent the expansion of the center of the metal base and the uneven heat accumulation on the metal base.

### Second Embodiment

As shown in FIG. 3a, a substrate 300 of the embodiment is analogous/similar to that of the first embodiment, which is configured for securing of a photoelectric device chip/photoelectric device chips (not shown). The substrate 300 includes a metal base 310 and a dielectric layer 320.

Similarly to the first embodiment, the metal base 310 includes a die bonding region 321 and a peripheral region 322 surrounding the die bonding region 321. The die bonding region 321 is configured for securing the photoelectric device chip(s) (not shown) thereon.

The dielectric layer 320 is disposed on the metal base 310 and located in the peripheral region 322 to define the die bonding region 321. In general, a geometrical center of the metal base 310 is corresponding to the center of the die bonding region.

The material of the metal base 310 can be a mirror aluminum, whose CTE generally is 23˜24 ppm/C. The thickness of the metal base 310 can be various specifications which are in a range of 0.2˜1.0 mm.

Distinguished from the first embodiment, the metal base 310 of the embodiment is further defined/formed with a groove 313 corresponding to the die bonding region 321. The groove 313 is filled with a thermally conductive filler 314 with high thermal conductivity or high CTE so as to enhance the heat dissipation efficiency of the die bonding region 321 by improving the heat conducting ability and achieve the objective of reducing the central temperature of the light-emitting surface.

Furthermore, with respect to the problem of uneven thermal distribution, the filling depth of the thermally conductive material can be adjusted to eliminate the heat stress cause by temperature differences. For instance, a filling density of the thermally conductive material in unit of volume of the metal base can be gradually reduced along a direction from the center to an edge of the die bonding region. In other words, the filling density of the thermally conductive filler in unit of volume of the metal base is maximal in the center of the die bonding region, and the filling density of the thermally conductive filler in unit of volume of the metal base gradually decreases along with approaching the edge of the die bonding region.

Specifically, in the illustrated embodiment, the metal base 310 is defined with one groove 313. A depth of the groove 313 gradually decreases along a direction from the center to an edge of the die bonding region 321 to gradually thin the thermally conductive filler 314 along the direction from the center to the edge of the die bonding region 321. The lowest position of the groove 313 with the most severe heat accumulation of the metal base 310 corresponding to the center of the die bonding region 321 requires to be filled with the thickest thermally conductive filler 314, which accelerates the heat transfer and reduces the possibility of deformation caused by relatively large stress generated in regions with high temperature capable of further rising temperature. Along with the farther distance from the central region of the die bonding region 321, the heat accumulation is decreased, and required thicknesses of the thermally conductive filler 314 correspondingly are gradually reduced. As shown in FIG. 3a, the filled thermally conductive filler 314 appears a structure of a deep center with gradual shallow edges.

The material of the thermally conductive filler 314 can be a thermally conductive filler 314 with high thermal conductivity or high CTE. For instance, if the metal base 310 is aluminum whose thermal conductivity is 237 W/mnK, the thermally conductive filler 314 can be a filler with high thermal conductivity such as gold whose thermal conductivity is 317 W/mK, copper whose thermal conductivity is 401 W/mK, silver whose thermal conductivity is 429 W/mK or graphene whose thermal conductivity is 5300 W/mK, which can satisfy the requirement of the thermal conductivity of the thermally conductive filler higher than that of the metal base; or the thermally conductive filler 314 can be a thermally conductive filler with high CTE, such as lead whose CTE is 26 ppm/° C., cadmium whose CTE is 41 ppm/° C., magnesium whose CTE is 29.3 ppm/C, zinc whose CTE is 36 ppm/° C. or tin whose CTE is 26.7 ppm/° C. If the metal base 310 is cooper whose CTE is 17.6 ppm/° C., the thermally conductive filler with high CTE has more candidates, such as aforementioned gold whose thermal conductivity is 317 W/mK, copper whose thermal conductivity is 401 W/mK, silver whose thermal conductivity is 429 W/mK and graphene whose thermal conductivity is 5300 W/mK are qualified; the criterion is the CTE of the thermally conductive filler to be larger than CTE of the metal base.

The structure of the groove 313 has multiple choices. For instance, the groove 313 of the embodiment is bowl-shaped, and the thermally conductive filler 314 correspondingly is bowl-shaped.

As shown in FIG. 3b, the embodiment further provides a photoelectric device 302 equipped with the substrate 300. The photoelectric device 302 includes a number of photoelectric device chips 301, the substrate 300, and a first electrode 304 (e.g. negative electrode) as well as a second electrode 305 (e.g. positive electrode) disposed on the substrate. The photoelectric device chips 301 are securely mounted on the metal base 310 and corresponding to the die bonding region 321. The photoelectric device chips 301 are electrically connected with the first electrode 304 and the second electrode 305. The first electrode 304 and the second electrode 305 are fixed on the metal base 310 and corresponding to the outside of the dielectric layer 320.

The embodiment introduces the thermally conductive filler 314 into the die bonding region 321 of the LED substrate 300. The filling depth of the thermally conductive filler 314 in the die bonding region 321 gradually reduces from the center to edges according to different heat accumulation degrees, so as to accelerate the heat conducting ability of the central region of the light-emitting surface and reduce the temperature differences among respective regions of the light-emitting surface, which results in unifying the entire temperature.

### Third Embodiment

A substrate 400 of the embodiment is analogous to that of the second embodiment. A difference is that the embodiment further improves the structure of the thermally conductive filler.

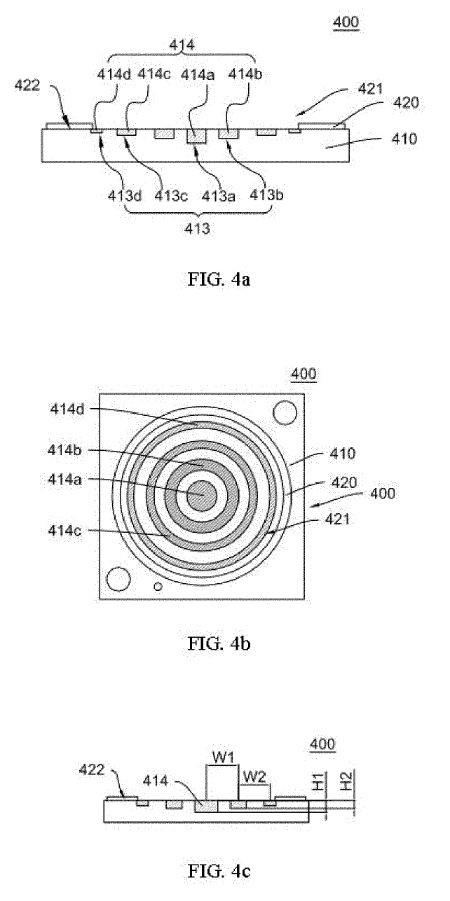

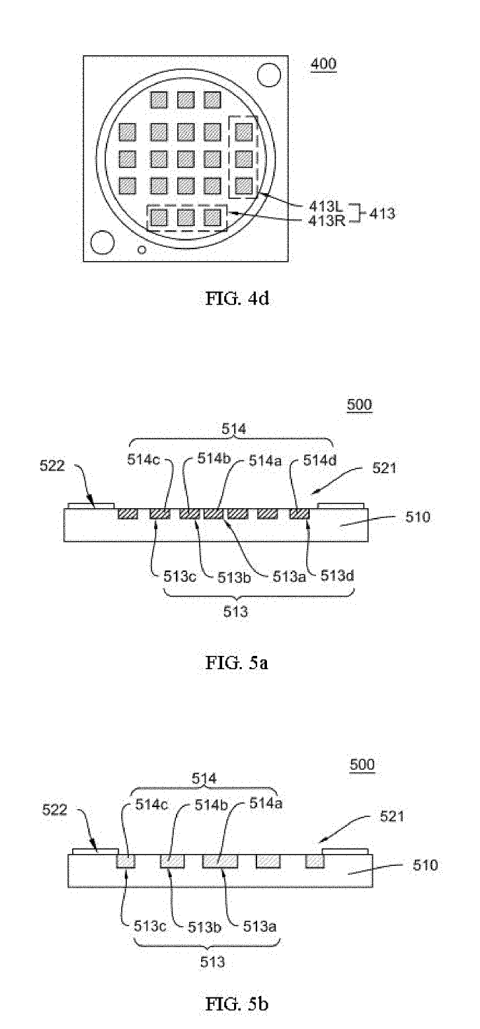

As shown in FIG. 4a and FIG. 4b, a metal base 410 of the embodiment further includes: defining numerous grooves 413 corresponding to the die bonding region 421. For instance, the embodiment includes a first groove 413a, a second groove 413b, a third groove 413c and a fourth groove 413d. The numerous grooves 413 are filled with thermally conductive fillers 414. For example, the embodiment includes a first filler 414a, a second filler 414b, a third filler 414c and a fourth filler 414d to enhance the heat conducting ability for promoting the heat dissipation efficiency of the metal base 410 with the die bonding region 421 and achieving the objective of reducing the temperature of geometrical center of the light-emitting surface 410.

The CTE of the thermally conductive fillers 414 is preferably higher than CTE of the metal base 410, and/or the thermal conductivity of the thermally conductive fillers 414 is higher than the thermal conductivity of the metal base 410. The material of the thermally conductive filler can be referred to that illustrated in the second embodiment.

Specifically, the first groove 413a can locate at the geometrical center of the metal base 410; the second groove 413b can be a ring that surrounds the first groove 413a; the third groove 413c can be a ring to surround the second groove 413b; the fourth groove 413d can be a ring to surround the third groove 413c; an nth groove (if it exists) can be arranged according to the rule. Therefore, the first groove 413a, the second groove 413b, the third groove 413c, the fourth groove 413d, . . . , the nth groove respectively are filled with the first filler 414a, the second filler 414b, the third filler 414c, the fourth filler 414d . . . the nth filler (which if exists). Filling depths H, opening areas of the grooves or distances W among adjacent grooves 413 can be adjusted according to various degrees of heat accumulation of the light-emitting surface, so as to obtain appropriate thermally conductive fillers 414.

Furthermore, as shown in FIG. 4b, opening widths of the first groove 413a, the second groove 413b, the third groove 413c and the fourth groove 413d in the embodiment are the same; the depths H are gradually reduced along a direction from the center to an edge of the die bonding region 421. Correspondingly, depths H of the first filler 414a, the second filler 414b, the third filler 414c and the fourth filler 414d are gradually reduced along the direction from the center to the edge of the die bonding region 421, which also can meet the requirement that: a filling density of the thermally conductive filler filled in unit of volume of the metal base is gradually reduced along a direction from the center to the edge of the die bonding region.

In other embodiments, the number of the grooves can further be two, three or more; grooves in the same row/column can be parallel or not; adjacent grooves can be symmetrical or not, and be connected or not; sizes of different grooves can be equal or not, such as the depths of grooves gradually reduce from the center to an edge. In addition, the filling depths H, the opening areas of the grooves or distances W of adjacent grooves 413 can be adjusted according to various degrees of heat accumulation of the light-emitting surface so as to obtain appropriate thermally conductive fillers 414.

The embodiment further provides calculation methods of depths of grooves/thermally conductive fillers.

As shown in FIG. 4c, opening areas of the grooves are supposed to be the same, a distance from the bottom of the groove to the upper surface of the metal base is defined as the depth of the groove, and the thickness of the thermally conductive filler in the groove can be regarded as the depth of the groove. The first groove located at the center of the die bonding region is set to be filled with the first filler, the thickness of the first filler is H_{tcf}. A coincidence relation between the thickness H_{mb} of the metal base and the thickness H_{tcf} of the first filler is shown as formula 1:

H_{tcf}*CTE_{tof}*T_{tcf}=H_{mb}*CTE_{mb}*T_{mb} Formula 1;

Where the CTE_{tcf} and CTE_{mb} respectively represent coefficients of thermal expansion of the first filler and the metal base; T_{tcf} and T_{mb} respectively represent maximal temperatures of the first filler and the metal base. Under ideal conditions, T_{tcf} is equal to T_{mb}, which indicates the temperature of the first filler in the central position of the die bonding region located at the metal base can be regarded to be identical to the temperature of the metal base. The formula 1 describes the size relation of the metal base and the first filler. Therefore, the thickness H_{tcf} of the first filler in the central position of the die bonding region can be obtained by the formula 1.

Next, the thickness of the filler adjacent to the first filler can be obtained by combining formula 1 and formula 2.

H₁*CTE₁*T₁=Hₙ*CTEₙ*Tₙ

Where T₁ and Tₙ respectively represent temperatures of the first filler and the nth filler. T₁ and Tₙ satisfy the corresponding relation as shown in formula 2:

T₁=Tₙ+T_{tg}*Wₙ Formula 2;

Where T_{tg} is no higher than 2° C./mm; Wₙ is a filling distance between the first filler and the nth filler. Formula 2 shows the size relation between fillers.

For instance, if it is expected to obtain the filling depth H₂ of the second filler, a predetermined distance W₁ between the first filler and the second filler can be substituted into formula 1 and formula 2 to obtain:

H₁*CTE₁*(T₂+T_{tg}*W₁)=H₂*CTE₂*T₂

Therefore, based on some predetermined factors, the minimal depth of each groove can be obtained according to formula 1 and formula 2, which permits the process of arranging thermally conductive fillers to be more accurate and effective, and the heat conducting effect can be controlled and regulated as well.

Apparently, the grooves 413 or thermally conductive fillers 414 can further be other arrangements or shapes. As shown in FIGS. 4c and 4d, the grooves 413 are arranged as an array in the die bonding region 421 to provide numerous parallel groove rows 413L and numerous parallel groove columns 413R. Moreover, openings of grooves 413 appear to be rectangular, opening areas of grooves 413 are the same, and depths H of grooves are determined based on the rule of gradual reduction from the center to an edge of the die bonding region 421. The grooves in the same row/column can be parallel or not; adjacent grooves can be symmetrical or not, and be connective or not; sizes of grooves can be the same or not, such as the groove depths are gradually shallow from the center to the edges or the same.

The temperature gradient of the metal base in the embodiment is restricted to 2° C./mm, which can guarantee the difference between Tj of the photoelectric device chip with the maximal temperature and the average Tj is lower than 5° C., so as to ensure the reliability of the photoelectric device.

In the embodiment, the thermally conductive filler is divided into multiple individual thermally conductive fillers, so as to allow the adjustment of the thermally conductive filler to be more flexible. Shapes and/or materials of the respective thermally conductive fillers can be different. The material of the thermally conductive filler in the central region of the die bonding region with considerable heat accumulation can be a material with high thermal conductivity so as to prevent the deformation caused by the stress resulting from heat accumulation, or a filling material with relatively high CTE to generate a compressive stress for neutralizing the intensification of raising temperature caused by deformation resulting from high temperature caused tensile stress. The material of the peripheral section of the die bonding region can be the thermally conductive material with relatively low CTE that is no less than CTE of the metal base, which can reduce the compressive stress to some extent.

### Fourth Embodiment

The embodiment is analogous to the third embodiment. A difference is that the embodiment further improves the structure of the thermally conductive filler.

For instance, as shown in FIG. 5a, grooves 513 of the embodiment include a first groove 513a, which can be located in the geometrical center of a metal base 510; the second groove 513b surrounds the first groove 513a; the third groove 513c surrounds the second groove 513b; the fourth groove 513d surrounds the third groove 513c; the nth filler (if it exists) can be arranged according to the rule.

Furthermore, opening areas of grooves and depths of the first groove 513a, the second groove 513b, the third groove 513c and the fourth groove 513d are the same; correspondingly, the first groove 513a, the second groove 513b, the third groove 513c and the fourth groove 513d respectively are filled with the first filler 514a, the second filler 514b, the third filler 514c and the fourth filler 514d. Filling areas and depths of the first filler 514a, the second filler 514b, the third filler 514c and the fourth filler 514d are the same. As the central region of the die bonding region 521 accumulates the most heat, a distance between the first groove 513a and the second groove 513b, a distance between the second groove 513b and the third groove 513c and a distance between the third groove 513c and the fourth groove 513d are sequentially increased; the closer to the high temperature region, the larger effective area of the thermally conductive filler is, which can achieve the objective of enhancing the heat conducting efficiency of the central region of the light-emitting surface; the requirement on heat conducting gradually reduces along with the extension from the central region to peripheral regions, distances among the second filler 514b, the third filler 514c and the fourth filler 514d can be gradually increased so as to unify the temperatures of various regions of the light-emitting surface and reduce the temperature difference.

As another example shown in FIG. 5b, depths of the first groove 513a, the second groove 513b and the third groove 513c can be predetermined to be the same; opening areas of the first groove 513a, the second groove 513b and the third groove 513c gradually reduce, and distances of every adjacent two of the grooves 513a˜513c sequentially increase. The first groove 513a, the second groove 513b and the third groove 513c respectively are filled with the first filler 514a, the second filler 514b and the third filler 514c. Correspondingly, depths of the first filler 514a, the second filler 514b and the third filler 514c are the same; heat conducting areas of the first filler 514a, the second filler 514b and the third filler 514c gradually reduce, and distances of every adjacent two of the fillers 514a-514c sequentially increase; the closer to the high temperature region, the larger effective area of the thermally conductive filler is, which can achieve the objective of enhancing the heat conducting efficiency of the central region of the light-emitting surface; the requirement of heat conducting ability gradually reduces along with the extension from the central region to peripheral regions, filling areas of the second filler 514b and the third filler 514c can be gradually reduced to unify the temperatures of various regions of the light-emitting surface and reduce the temperature difference.

Identically, the arrangement of the thermally conductive fillers of the embodiment further satisfies the rule that: the filling density of the thermally conductive filler filled in unit of volume of the metal base is gradually reduced along a direction from the center to the edge of the die bonding region.

The temperature gradient of the metal base of the embodiment is restricted to 2° C./mm, which can guarantee the difference between Tj of the photoelectric device chip with the maximal temperature and the average Tj is lower than 5° C. for ensuring the reliability of the photoelectric device.

In the embodiment, the thermally conductive filler is divided into multiple individual thermally conductive fillers, so as to allow the adjustment of the thermally conductive filler to be more flexible. Shapes and/or materials of the respective thermally conductive fillers can be different. The arrangement manners of the fillers further have multiple options. The material of the thermally conductive fillers can be referred to those shown in the third embodiment, which preferably is the thermally conductive filler with CTE higher than that of the metal base, and/or the thermal conductivity of the thermally conductive filler is larger than that of the metal base.

The thermally conductive filler of the embodiment is divided into multiple thermally conductive fillers, which are filled in the metal base by the grooves defined in the metal base. The filling depths and/or the opening areas are predetermined to be the same, the arrangement and influence factors of grooves such as opening areas of grooves and filling distances can be flexibly regulated. Heat conducting efficiencies of various sections of the die bonding region are regulated to maximize the thermal conductivity of the central section and minimize the thermal conductivity of the peripheral sections of the die bonding region, which finally achieve the unified temperature of the entire light-emitting surface and reduce the temperature difference.

### Fifth Embodiment

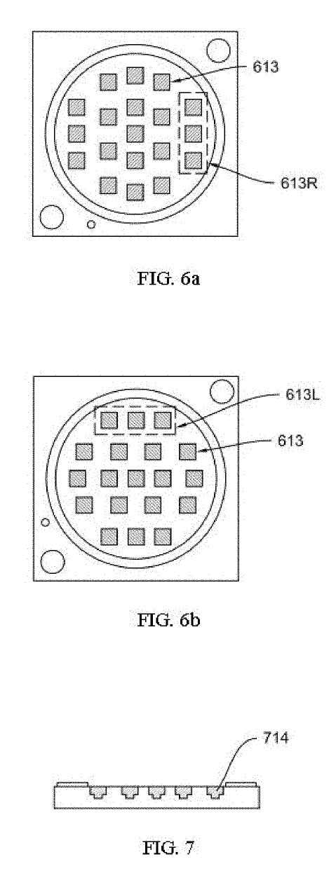

The embodiment is analogous to the fourth embodiment, and a difference therebetween is the embodiment further improves the structure of the thermally conductive filler. As shown in FIG. 6a, grooves 613 are arranged to be multiple parallel groove columns 613R in the metal base, and arranged to be staggered in the row direction.

As shown in FIG. 6b, the grooves 613 can further be arranged to be multiple parallel groove rows 613L in the metal base, and arranged to be staggered in the column direction.

### Sixth Embodiment

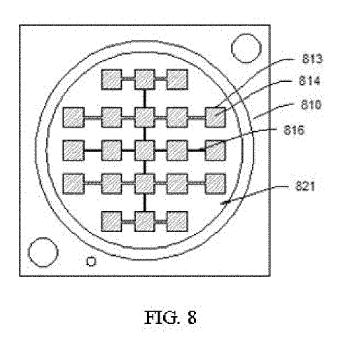

The embodiment is analogous to the fourth embodiment, and a difference therebetween is the embodiment further improves the structure of the thermally conductive filler. As shown in FIG. 7, thermally conductive fillers 714 can further be several thermally conductive fillers whose respective shape is reverse trapeziform.

Shapes and structures of the thermally conductive filler of the embodiment of the disclosure will not be restricted thereto; the thermally conductive filler can further be triangular, hemispheric, rectangular or other geometric shapes.

### Seventh Embodiment

The embodiment is analogous to the second embodiment, and a difference therebetween is the embodiment further improves the structure of the thermally conductive filler. As shown in FIG. 8, a metal base 810 corresponding to a die bonding region 821 is defined with connective grooves 816 each of which communicates every two adjacent grooves 813, and the connective grooves 816 are filled with thermally conductive fillers 814.

Preferably, grooves 813 are communicated through connective grooves 816 to integrate each originally individual filler to be an integral thermally conductive filler 814.

The structure is benefit for rapidly manufacturing processes of the thermally conductive filler. The material of the thermally conductive filler generally can be metal or semi metal graphene, which is liquid at melting point to be filled in grooves and solidified by cooling. Channels are defined between grooves in the embodiment to substitute the liquid thermally conductive material filled in one groove flowing into other grooves through the channels to obtain the thermally conductive fillers defined by predetermined parameters after cooling down for the necessity to separately fill the liquid thermally conductive material into each of the grooves. The choice of materials of the thermally conductive filler can be referred to those in the third embodiment.

Thermally conductive connecters between thermally conductive fillers in the embodiment can both reduce the difficulty in manufacturing thermally conductive fillers and remain the merit of flexibility and adjustability of thermally conductive fillers, which better the performance of thermally conductive fillers.

The aforementioned first embodiment, second embodiment, third embodiment, fourth embodiment and fifth embodiment merely are exemplary embodiments of the disclosure. On the prerequisite of technical features being not conflictive, structures being not contradictive and the inventive purpose of the disclosure being not obeyed, the embodiments can be freely combined for application.

What is claimed is:

1. A substrate, configured for securing of a photoelectric device chip; wherein the substrate comprises:
a metal base, comprising a die bonding region and a peripheral region surrounding the die bonding region, and the die bonding region being configured for securing the photoelectric device chip thereon;
a dielectric layer, disposed on the metal base and located in the peripheral region to define the die bonding region;
wherein the metal base is defined with at least one groove corresponding to the die bonding region, the at least one groove is filled with a thermally conductive filler, and a filling density of the thermally conductive filler in unit of volume of the metal base is gradually reduced along a direction from a center to an edge of the die bonding region.

2. The substrate according to claim 1, wherein depths of the at least one groove are gradually reduced along the direction from the center to the edge of the die bonding region, so as to allow filling depths of the thermally conductive filler to be gradually reduced along the direction from the center to the edge of the die bonding region.

3. The substrate according to claim 1, wherein opening areas of the at least one groove are gradually reduced along the direction from the center to the edge of the die bonding region, so as to allow heat conducting areas of the thermally conductive filler to be gradually reduced along the direction from the center to the edge of the die bonding region.

4. The substrate according to claim 1, wherein distances among adjacent grooves are gradually increased along the direction from the center to the edge of the die bonding region, so as to allow heat conducting areas of the thermally conductive filler to be gradually reduced along the direction from the center to the edge of the die bonding region.

5. The substrate according to claim 2, wherein the metal base corresponding to the die bonding region is defined with connective channels to communicate every two adjacent grooves, and the connective channels are filled with the thermally conductive filler.

6. The substrate according to claim 3, wherein the metal base corresponding to the die bonding region is defined with connective channels to communicate every two adjacent grooves, and the connective channels are filled with the thermally conductive filler.

7. The substrate according to claim 4, wherein the metal base corresponding to the die bonding region is defined with connective channels to communicate every two adjacent grooves, and the connective channels are filled with the thermally conductive filler.

8. The substrate according to claim 2, wherein multiple grooves are arranged as an array in the die bonding region and whereby forming a plurality of parallel groove rows and a plurality of parallel groove columns.

9. The substrate according to claim 3, wherein multiple grooves are arranged as an array in the die bonding region and whereby forming a plurality of parallel groove rows and a plurality of parallel groove columns.

10. The substrate according to claim 4, wherein multiple grooves are arranged as an array in the die bonding region and whereby forming a plurality of parallel groove rows and a plurality of parallel groove columns.

11. The substrate according to claim 2, wherein multiple grooves are arranged as a plurality of parallel groove columns in the die bonding region, and arranged to be staggered in a row direction; or the multiple grooves are arranged as a plurality of parallel groove rows in the die bonding region, and arranged to be staggered in a column direction.

12. The substrate according to claim 3, wherein multiple grooves are arranged as a plurality of parallel groove columns in the die bonding region, and arranged to be staggered in a row direction; or the multiple grooves are arranged as a plurality of parallel groove rows in the die bonding region, and arranged to be staggered in a column direction.

13. The substrate according to claim 4, wherein multiple grooves are arranged as a plurality of parallel groove columns in the die bonding region, and arranged to be staggered in a row direction; or the multiple grooves are arranged as a plurality of parallel groove rows in the die bonding region, and arranged to be staggered in a column direction.

14. The substrate according to claim 1, wherein a thermal conductivity of the thermally conductive filler is higher than a thermal conductivity of the metal base.

15. The substrate according to claim 1, wherein a coefficient of thermal expansion of the thermally conductive filler is higher than a coefficient of thermal expansion of the metal base.

16. A photoelectric device, comprising a plurality of photoelectric device chips, a substrate, and a first electrode as well as a second electrode disposed on the substrate;
wherein the substrate comprises:
a metal base, comprising a die bonding region and a peripheral region surrounding the die bonding region;
a dielectric layer, disposed on the metal base and located in the peripheral region to define the die bonding region;
wherein the metal base is formed with at least one groove corresponding to the die bonding region, the at least one groove is filled with a thermally conductive filler, and a filling density of the thermally conductive filler in unit of volume of the metal base is gradually decreased along a direction from a center to an edge of the die bonding region;
wherein the plurality of photoelectric device chips are secured in the die bonding region of the metal base of the substrate and electrically connected with the first electrode and the second electrode, the first electrode and the second electrode are located in the peripheral region of the metal base.

17. The photoelectric device according to claim 16, wherein a ratio of a thickness of the dielectric layer to a thickness of the metal base is greater than 0.5 and smaller than 1.

18. The photoelectric device according to claim 16, wherein the at least one groove is a single groove with gradually decreased depths along the direction from the center to the edge of the die bonding region.

19. The photoelectric device according to claim 16, wherein the at least one groove is multiple grooves; and the multiple grooves satisfy at least one of following conditions that: depths of the multiple grooves are gradually decreased along the direction from the center to the edge of the die bonding region, distances of every adjacent two of the multiple grooves are gradually increased along the direction from the center to the edge of the die bonding region, and opening areas of the multiple grooves are gradually decreased along the direction from the center to the edge of the die bonding region.

20. The photoelectric device according to claim 16, wherein the at least one groove comprises multiple grooves, and the multiple grooves are nested rings and spaced from one another.
